(19) United States
(12) Patent Application Publication
(10) Pub. No.: US 2015/0003859 A1
(43) Pub. Date: Jan. 1, 2015

(54) AIR INTAKE MECHANISM OF ELECTRONIC APPARATUS, AND IMAGE FORMING APPARATUS PROVIDED WITH AIR INTAKE MECHANISM

(71) Applicant: KYOCERA Document Solutions Inc., Osaka-shi (JP)

(72) Inventor: Keiichi Tanida, Osaka (JP)

(21) Appl. No.: 14/372,177

(22) PCT Filed: Oct. 17, 2012
(86) PCT No.: PCT/JP2012/076754

§ 371 Date: Jul. 14, 2014

(30) Foreign Application Priority Data
Feb. 22, 2012 (JP) 2012-036589

(51) Int. Cl. G03G 21/20; G06F 1/20

(52) U.S. Cl. CPC H05K 7/20145; H05K 7/20181
USPC 399/92; 361/679.51

(57) ABSTRACT

This air intake mechanism is configured of a first louver (23), a second louver (30), and an axial fan (33). The first louver (23) is an annular opening between an outer circular section (25), which is concentric to the rotating axis (rotation center) of the axial fan (33), and an inner circular section (27), which is concentric to the outer circular section (25). The second louver (30) is configured of a plurality of linear slits (30a), which are parallel to each other. The opening width (d2) of each of the slits (30a) that constitutes the second louver (30) is smaller than the opening width (d1) of the first louver (23).

### TECHNICAL FIELD

The present disclosure relates to an air intake mechanism that introduces external air into OA machines such as a digital copy machine, a laser printer and the like and into electronic apparatuses such as a home appliance and the like.

### BACKGROUND ART

In electronic apparatuses such as a copy machine, a personal computer, a television and the like, various control boards, on which a plurality of electronic components are mounted, are used. In such control boards, there is a risk that electromagnetic noise occurring from the electronic components on the control boards leak further to outside to adversely affect peripheral electronic apparatuses. As a measure to prevent the leakage of the electromagnetic noise, a method is employed, in which the control board is housed in a metal electric box that blocks the electromagnetic noise.

On the other hand, generally, the control board generates heat because of operation of an electronic apparatus; accordingly, it is necessary to form a cooling mechanism that prevents deterioration and breakage of the electronic component caused by the heat generation. Because of this, various technologies are proposed to cool the control board housed in the electric box. For example, a patent document 1 discloses a structure in which in a case where a both-side paper-sheet supply unit is installed adjacently to a power-source unit, a cooling fans is installed at a position opposing an air opening of the power-source unit and an air intake opening is formed to introduce external air into the power-source box.

However, in the case where a fan is used to cool the control board, noise (wind sound) occurs when an airflow due to the fan passes through the air opening. In recent years, the demand for reducing noise is increasing, and measures against a wind sound that is a factor of noise are becoming important, but the method of the patent document 1 cannot reduce the wind sound.

Accordingly, a method is proposed to reduce a wind sound that is produced when an airflow passes through an air opening. A patent document 2 discloses a technology in which an air exhaling fan is disposed on an extended line of a main cooling wind path to make the main cooling wind path linear in a power-source unit. Besides, an air exhaling louver covering an outer surface of the air exhaling fan is made concentric, whereby vibration of a transfer material at a paper sheet carry portion is curbed to achieve low noise.

Besides, a patent document 3 discloses whether to open a shape of a louver disposed near an axis-flow fan in a centrifugal direction from an axis center or to open the louver concentrically from the axis center. And, a method is disclosed, which raises air exhaling efficiency by means of the opening and reduces a wind sound that occurs at a louver portion.

### CITATION LIST

### Patent Literature

PLT1: JP-A-2005-227724
PLT2: JP-A-1998-198256
PLT1: JP-A-2005-10494

### SUMMARY OF INVENTION

### Technical Problem

In a case where a control board housed in a power-source box is cooled by means of an air intake fan, it is necessary to make an airflow taken in by the fan from outside the apparatus pass successively through two louvers that are formed in an outer cover and an electric box. However, in the methods of the patent documents 2 and 3, it is possible to reduce a wind sound that is produced when an airflow passes through one louver, but it is impossible to sufficiently reduce a wind sound due to interference of the airflow that is produced when the airflow passes successively through the two louvers.

In the meantime, here, occurrence of a wind sound during a cooling time of the control board housed in the electric box is described. However, in a structure in which an electronic apparatus has an outer cover and an inner cover; and an airflow passes successively through two louvers formed in the outer cover and the inner cover, the same airflow interference as the above description occurs; accordingly, measures against the wind sound become necessary.

It is an object of the present disclosure to provide an air intake mechanism of an electronic apparatus that is able to reduce, by means of a simple structure, a wind sound that is produced when an airflow passes through two louvers that are formed in an outer cover and an inner cover.

### Solution to Problem

To achieve the above object, a first structure of the present disclosure is an air intake mechanism of an electronic apparatus that comprises: an axial-flow fan that introduces external air into an apparatus main body, an inner cover that is disposed outside the axial-flow fan and provided with a first louver through which an airflow produced by the axial-flow fan passes, and an outer cover that is disposed outside the inner cover and provided with a second louver through which the airflow produced by the axial-flow fan passes, the inner cover and the outer cover being disposed to oppose each other such that positions of the first louver and the second louver overlie each other, wherein the first louver is formed of an annular opening that is surrounded by an outer circular portion concentric with a rotation center of the axial-flow fan and an inner circular portion concentric with the outer circular portion that is supported by a support portion which protrudes inward from a circumferential rim portion of the outer circular portion, while the second louver is formed of a plurality of linear slits that are parallel to each other and have an opening width that is narrower than a distance between the outer circular portion and the inner circular portion, and the support portion is formed on a tangential line of the inner circular portion that extends from the circumferential rim portion of the outer circular portion toward the inner circular portion in a same direction as a circling direction of the airflow produced by the axial-flow fan.

Besides, a second structure of the present disclosure is an image forming apparatus that comprises the air intake mechanism having the above structure, wherein the inner cover is formed in an electric box in which a control board is housed, and the axial-flow fan introduces external air into the electric box via the second louver and the first louver.

### Advantageous Effects of Invention

According to the first structure of the present disclosure, a plurality of airflows, which flow in through the second louver that is formed of the plurality of linear slits, join each other and flow to the first louver that is formed of the annular opening. And, the airflows pass through the first louver, thereafter, are pulled into the axial-flow fan; accordingly, the airflows flowing in through the second louver do not branch when passing through the first louver, so that it is possible to curb occurrence of a wind sound. Besides, by making the opening width of the annular opening that forms the first louver wider than the opening width of the linear slit that forms the second louver, it is also possible to curb occurrence of noise produced by vibration of the inner cover. Accordingly, it is possible to achieve quietness of the electronic apparatus and improve cooling effect in the electronic apparatus. Further, by forming the support portion, which supports the inner circular portion of the first louver, on the tangential line of the inner circular portion that extends from the circumferential rim portion of the outer circular portion toward the inner circular portion in the same direction as the circling direction of the airflow that is produced by the axial-flow fan, it is possible to reduce further interference between the support portion and the airflow that is produced by the axial-flow fan.

Besides, according to the second structure of the present disclosure, by incorporating the air intake mechanism having the above first structure, it is possible to achieve quietness of the image forming apparatus and smoothly pull cold air outside the image forming apparatus into the electric box; accordingly, cooling effect for the control board also improves.

### BRIEF DESCRIPTION OF DRAWINGS

FIG. 1 is a schematic sectional view showing a whole structure of an image forming apparatus 100 that comprises an air intake mechanism according to the present disclosure.

FIG. 2 is a partial perspective view showing an state of the image forming apparatus 100 in which an outer cover 20 is opened.

FIG. 3 is a front view of a first louver 23 that is formed in a cover portion 21a of an electric box 21.

FIG. 4 is a front view of a second louver 30 that is formed in the outer cover 20.

FIG. 5 is a partial sectional view near the first louver 23 and the second louver 30 in a state where the outer cover 20 of the image forming apparatus 100 is closed.

FIG. 6 is a simulation view showing directions of airglows that successively pass through the second louver 30 and the first louver 23.

### DESCRIPTION OF EMBODIMENT

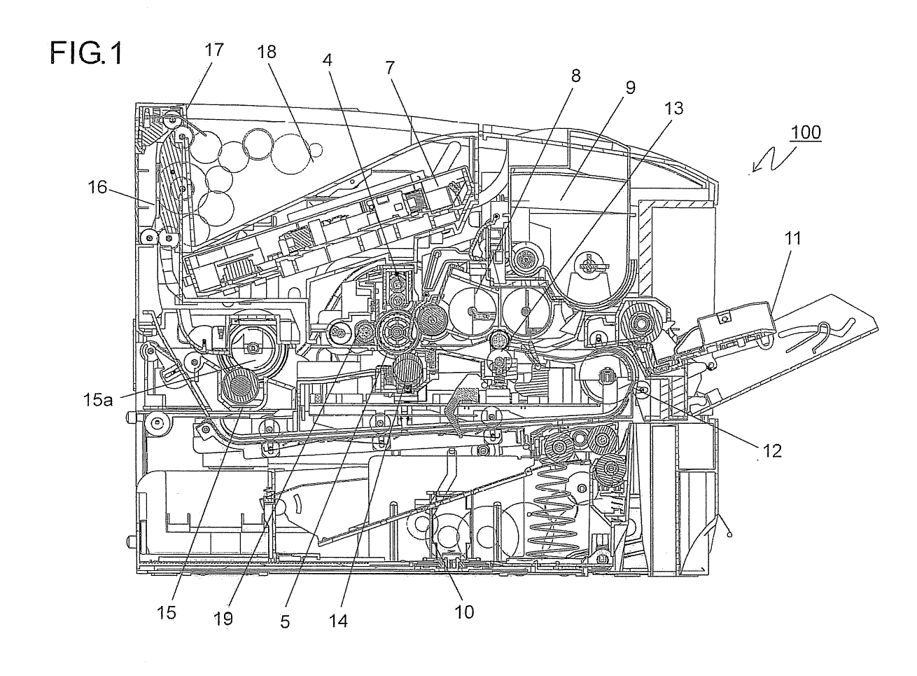

Hereinafter, an embodiment of the present disclosure is described with reference to the drawings. FIG. 1 is a side sectional view showing an internal structure of the image forming apparatus 100 that comprises an air intake mechanism according to the present disclosure. In the image forming apparatus (e.g., monochromic printer) 100, in a case of performing an image forming operation, a photosensitive drum 5, which rotates clockwise in the drawing, is evenly electrified by an electrification unit 4. And, an electrostatic latent image is formed on the photosensitive drum 5 by means of a laser beam from a light exposure unit (laser scan unit and the like) 7 based on document image data, and a developer (hereinafter, called a toner) is attached to the electrostatic latent image by a development unit 8 to form a toner image.

A toner supply to this development unit 8 is performed from a toner container 9. In the meantime, the image data are transmitted from a personal computer (not shown) and the like. Besides, an electricity removal device (not shown) for removing residual charges on a surface of the photosensitive drum 5 is disposed in a downstream side with respect to a cleaning device 19.

A paper sheet is carried from a paper sheet supply cassette 10 or a manual supply tray 11 to the photosensitive drum 5 on which the toner image is formed as described above via a paper sheet carry path 12 and a pair of registration rollers 13. And, the toner image formed on the surface of the photosensitive drum 5 is transferred to the paper sheet by a transfer roller 14 (image transfer portion). Thereafter, the paper sheet, to which the toner image is transferred, is separated from the photosensitive drum 5 and carried to a fixing portion 15 that has a pair of fixing rollers 15a, so that the toner image is fixed. The paper sheet passing through the fixing portion 15 is carried to an upper portion of the apparatus by a paper sheet carry path 16, and ejected to an ejection tray 18 by a pair of ejection rollers 17.

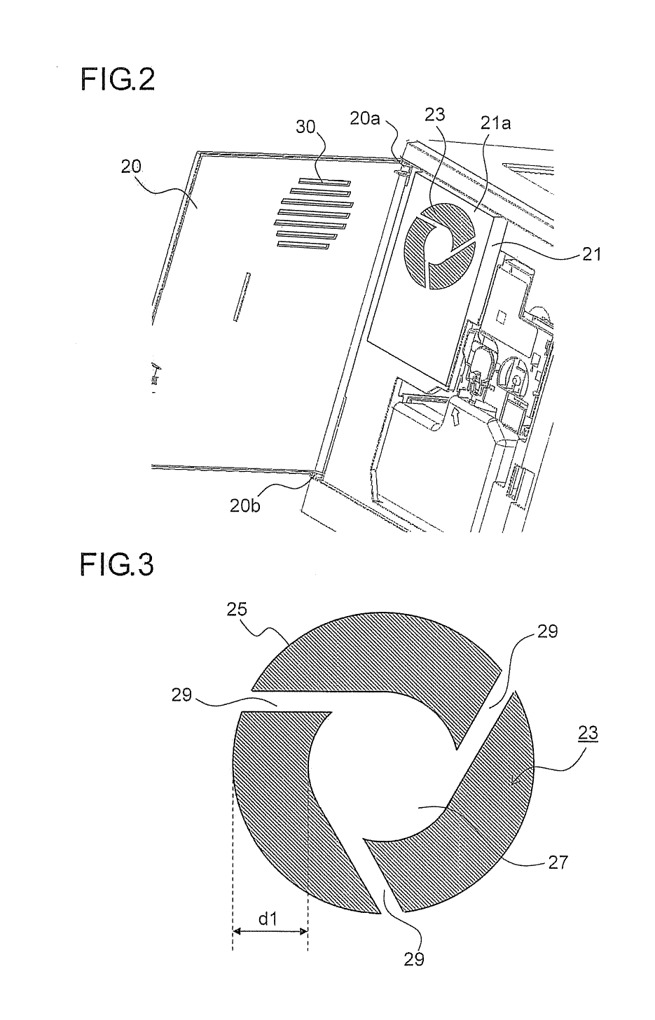

FIG. 2 is a perspective view of the image forming apparatus 100 showing a state in which the outer cover 20 is opened. The outer cover 20 is supported by a main body of the image forming apparatus 100 by means of an upper rotation pivot 20a and a lower rotation pivot 20b. The outer cover 20 is openable and closable in a horizontal direction about a rotation axis that connects the rotation pivots 20a and 20b to each other.

An electric box 21 is disposed under the outer cover 20. A control board 31 (see FIG. 5) is housed in the electric box 21. By forming the electric box 21 by means of a metal plate, electromagnetic noise occurring from the control board 31 is prevented from leaking to outside. Besides, an axial-flow fan 33 (see FIG. 5) for cooling the control board 31 is disposed in the electric box 21.

A frontal cover portion 21a of the electric box 21 is provided with a first louver 23. Besides, the outer cover 20 is provided with a second louver 30 at a position that overlies the first louver 23 when the outer cover 20 is closed. The first louver 23, the second louver 30, and the axial-flow fan 33 compose the air intake mechanism of the image forming apparatus 100.

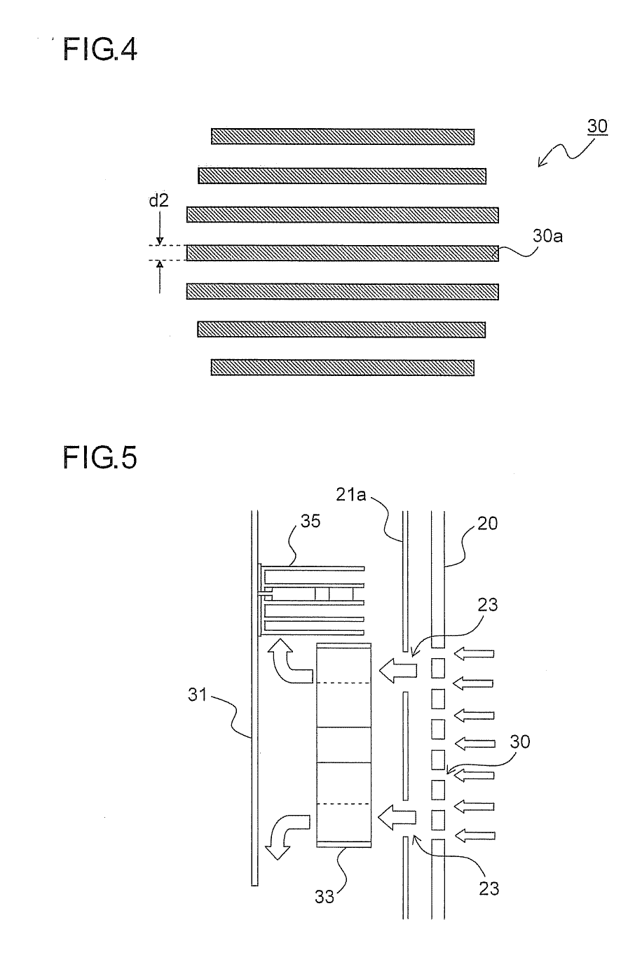

FIG. 3 is a front view of the first louver 23 formed in the cover portion 21a of the electric box 21, and FIG. 4 is a front view of the second louver 30 formed in the outer cover 20. As shown in FIG. 3, the first louver 23 is an annular opening that is surrounded by an outer circular portion 25 concentric with a rotation axis (rotation center) of the axial-flow fan 33 and an inner circular portion 27 concentric with the outer circular portion 25. The inner circular portion 27 is supported by the cover portion 21a by means of three support portions 29 that protrude inward from a circumferential rim portion of the outer circular portion 25. Each support portion 29 is formed on a tangential line of the inner circular portion 27 that extends from the circumferential rim portion of the outer circular portion 25 toward the inner circular portion 27. The extending direction from the outer circular portion 25 of the support portion 29 toward the inner circular portion 27 is the same direction as a circling direction (clockwise direction in FIG. 3) of an airflow (circling flow) formed by the axis-flow fan 33.

As shown FIG. 4, the second louver 30 is composed of a plurality of linear slits 30a parallel to each other. And, an opening width d2 of each slit 30a is narrower than an opening width of the first louver 23, that is, a distance d1 (see FIG. 3) between the outer circular portion 25 and the inner circular portion 27.

FIG. 5 is a partial sectional view near the first louver 23 and the second louver 30 in a state where the outer cover 20 of the image forming apparatus 100 is closed. In the meantime, in FIG. 5, the right side is an outer portion of the image forming apparatus 100. In the state where the outer cover 20 is closed, the second louver 30, the first louver 23, the axial-flow fan 33, and the control board 31 are disposed in this order from the outside of the image forming apparatus 100. External air is pulled by the axial-flow fan 33 into the electric box 21 via the second louver 30 and the first louver 23 and is used to cool an electronic component 35 on the control board 31 and the like.

In the case where the axial-flow fan 33 is used as a cooling fan, it is known that the airflows before and behind the axial-flow fan 33 become a circling flow around the rotation axis of the fan. In the present embodiment, by forming the first louver 23 disposed in the cover portion 21a of the electric box 21 into the annular opening that is a circle concentric with the rotation axis of the axis-flow fan 33, interference between the first louver 23 and the airflow is effectively curbed.

On the other hand, it is preferable that the second louver 30 formed in the outer cover 20 is composed of the plurality of linear slits 30a parallel to each other for the purpose of preventing foreign matter from invading into the image forming apparatus 100 and reducing the forming cost of the outer cover 20. However, in the case where the second louver 30 formed of the plurality of linear slits 30a is placed over the first louver 23 formed of the annular opening concentric with the rotation axis of the axial-flow fan 33, the airflow, which passes through the second louver 30 to linearly flow in, interferes with the annular first louver 23 to produce a wind sound when passing through the annular first louver 23.

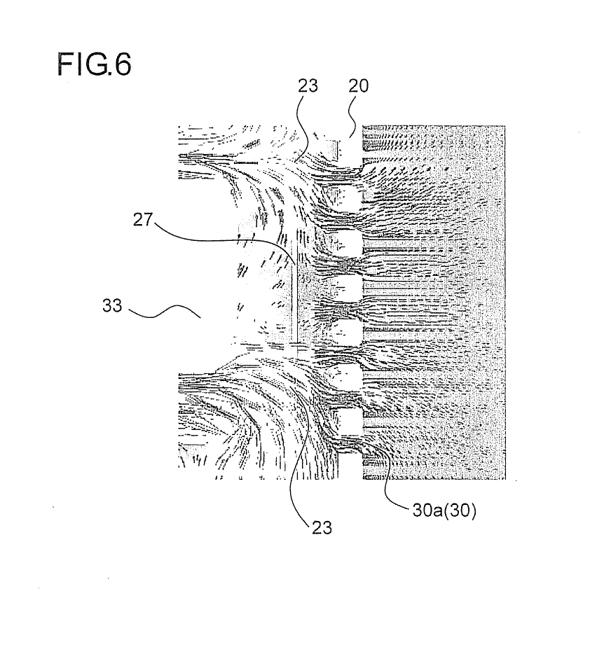

Accordingly, in the present disclosure, the opening width d2 (see FIG. 4) of the linear slit 30a composing the second louver 30 is made narrower than the opening width d1 (see FIG. 3) of the first louver 23. FIG. 6 is a simulation view showing directions of the airflows that successively pass through the second louver 30 and the first louver 23. In the meantime, in FIG. 6, dark and light portions of arrows indicate a speed difference between the airflows: the dark portion has a flow speed faster than the light portion.

As is apparent from FIG. 6, it is understood that the plurality of airflows linearly flowing in from the second louver 30 join each other, flow to the first louver 23, pass through the first louver 23, thereafter, are pulled into the axial-flow fan 33. As described above, the airflows flowing in from the second louver 30 do not branch again when passing through the first louver 23; accordingly, it is possible to curb occurrence of a wind sound. Besides, by making the opening width d1 of the first louver 23 wider than the opening width d2 of the second louver 30, the airflows flowing in from the second louver 30 do not collide with the cover portion 21a; accordingly, it is also possible to curb occurrence of noise caused by vibration of the cover portion 21a. Accordingly, it is possible to achieve quietness of the image forming apparatus 100. Besides, it is possible to smoothly pull external cold air outside the image forming apparatus 100 into the electric box 21; accordingly, cooling effect for the control board 31 also improves.

Further, the support portion 29 supporting the inner circular portion 27 of the first louver 23 is formed on the tangential line of the inner circular portion 27 that extends from the circumferential rim portion of the outer circular portion 25 toward the inner circular portion 27 in the same direction as the circling direction of the airflow (circling flow) formed by the axial-flow fan 33. In this way, it is possible to further reduce interference between the airflow formed by the axial-flow fan 33 and the support portion 29.

Besides, the present disclosure is not limited to the above embodiment, and various modifications are possible without departing from the spirit of the present disclosure. For example, in the above embodiment, the structure is described, in which the outer cover 20 is formed outside the electric box 21; the airflow successively passes through the second louver 30 of the outer cover 20 and the first louver 23 of the electric box 21. However, the electric box 21 is not limiting, and it is possible to apply, in the completely same way, a structure in which an inner cover overlying the outer cover 20 is disposed and the inner cover is provided with the first louver 23.

Besides, the present disclosure is applicable not only to the monochromic printer shown in FIG. 1 but also to other types of image forming apparatuses such as analog and digital types of monochromic copy machines, a color copy machine, a color printer, a facsimile and the like. Besides, it goes without saying that the present disclosure is also applicable to an air intake mechanism of an electronic apparatus other than the image forming apparatus.

### INDUSTRIAL APPLICABILITY

The present disclosure is usable for an air intake mechanism that introduces an airflow into an electronic apparatus by using an axial-flow fan and two louvers formed in an outer cover and an inner cover. Thanks to the use of the present disclosure, the air intake mechanism of an electronic apparatus is obtained, in which it is possible to easily reduce a wind sound that is produced when an airflow passes through the two louvers formed in the outer cover and the inner cover.

### REFERENCE SIGNS LIST

20 outer cover
21 electric box
21a cover portion (inner cover)
23 first louver
25 outer circular portion
27 inner circular portion
29 support portion
30 second louver
30a slit
31 control board
33 axial-flow fan
100 image forming apparatus

What is claimed is:

1. An air intake mechanism of an electronic apparatus comprising:
an axial-flow fan that introduces external air into an apparatus main body,
an inner cover that is disposed outside the axial-flow fan and provided with a first louver through which an airflow produced by the axial-flow fan passes, and
an outer cover that is disposed outside the inner cover and provided with a second louver through which the airflow produced by the axial-flow fan passes,
the inner cover and the outer cover being disposed to oppose each other such that positions of the first louver and the second louver overlie each other, wherein
the first louver is formed of an annular opening that is surrounded by an outer circular portion concentric with a rotation center of the axial-flow fan and an inner circular portion concentric with the outer circular portion that is supported by a support portion which protrudes inward from a circumferential rim portion of the outer circular portion, while the second louver is formed of a plurality of linear slits that are parallel to each other and have an opening width that is narrower than a distance between the outer circular portion and the inner circular portion, and
the support portion is formed on a tangential line of the inner circular portion that extends from the circumferential rim portion of the outer circular portion toward the inner circular portion in a same direction as a circling direction of the airflow produced by the axial-flow fan.

2. An image forming apparatus comprising the air intake mechanism according to claim 1, wherein
the inner cover is formed in an electric box in which a control board is housed, and the axial-flow fan introduces external air into the electric box via the second louver and the first louver.
